(19) United States
(12) Patent Application Publication
(10) Pub. No.: US 2023/0317822 A1
(43) Pub. Date: Oct. 5, 2023

(54) GATE SPACERS WITH ADJACENT UNIFORM EPITAXIAL MATERIAL

(71) Applicant: Intel Corporation, Santa Clara, CA (US)

(72) Inventors: Stephen M. CEA, Hillsboro, OR (US); Borna OBRADOVIC, Portland, OR (US); Rishabh MEHANDRU, Portland, OR (US); Jack T. KAVALIEROS, Portland, OR (US)

(21) Appl. No.: 17/711,434

(22) Filed: Apr. 1, 2022

(51) Int. Cl. H01L 29/66; H01L 29/06; H01L 29/08

(52) U.S. Cl. CPC H01L 29/66553; H01L 29/66545; H01L 29/0673; H01L 29/0847

(57) ABSTRACT

Embodiments described herein may be related to transistor structures where dimpled spacers, which may also be referred to as inner spacers or offset spacers, may be formed around gates within an epitaxial structure such that the epitaxial material adjacent to the dimpled spacer is uniform and/or defect free. In embodiments, forming the dimpled spacers occurs after epitaxial growth. Other embodiments may be described and/or claimed.

### FIELD

Embodiments of the present disclosure generally relate to the field of semiconductor packaging, and in particular to transistor structures with nano-ribbons.

### BACKGROUND

Continued growth in virtual machines, cloud computing, and portable devices will continue to increase the demand for high density transistors within chips and packages.

### BRIEF DESCRIPTION OF THE DRAWINGS

FIG. 1 shows a cross section side view of a PMOS and a NMOS gate cut that include dimpled spacers in a nano-ribbon structure, in accordance with various embodiments.

FIGS. 2A-2H illustrate stages in a legacy manufacturing process for creating a nano-ribbon structure with dimpled spacers.

FIGS. 3A-3F illustrate stages in a manufacturing process for creating nano-ribbon structures with dimpled spacers with defect free epitaxial layers, in accordance with various embodiments.

FIG. 4 illustrates an example process for manufacturing a transistor with nano-ribbon structures with dimpled spacers that allow epitaxial layers to grow defect free, in accordance with various embodiments.

FIGS. 5A-5B schematically illustrate a top view of an example die in wafer form and in singulated form, and a cross section side view of a package assembly, in accordance with various embodiments.

FIG. 6 illustrates a computing device in accordance with one implementation of the invention.

FIG. 7 illustrates an interposer that includes one or more embodiments of the invention.

### DETAILED DESCRIPTION

Embodiments described herein may be related to apparatuses, processes, systems, and/or and techniques directed to transistor structures where dimpled spacers, which may also be referred to as inner spacers or offset spacers, may be formed around gates within an epitaxial structure that includes a source and a drain, such that the epitaxial material adjacent to the dimpled spacer is uniform and/or defect free. In embodiments, this will effectively strain the channel of the transistor structure. In embodiments, this may be accomplished forming the dimpled spacers after epitaxial growth and/or after a dummy gate, which may be also known as a replacement metal gate (RMG) is removed.

In embodiments, by improving the uniformity and reducing the defects in the epitaxial material around the dimpled spacer, strain due to epitaxial S/Ds or due to lattice mismatch between the channels and substrate the strain the channels will be improved. This improves carrier transport and overall drive current. In legacy implementations, epitaxial recipes may be altered to encourage reduced defects of epitaxial material grown around dimpled spacers. However, these legacy approaches of growing epitaxy around dimpled spacers have had limited success.

In embodiments, epitaxial material may include silicon (Si) and silicon germanium (SiGe). In embodiments, using SiGe as channel material may achieve larger strains for the same source/drain quality. Using SiGe as both a channel and an epitaxial material may allow the dimpled spacers to be formed at the RMG because Si removal etch will not attack SiGe source/drain and etch them out causing yield impact.

In embodiments, forming dimpled spacers may use thinner channels relative to thickness under the spacers region in order to fill in the spaces from inside (below the RMG) while still etching off channels. In embodiments, forming the epitaxial source/drain on structures without dimpled spacers will result in defect free epitaxial, which will strain the channel. In addition, using SiGe as a channel material may achieve larger strains for the same source/drain quality, which should improve PMOS performance due to higher mobility/ballistic velocity.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

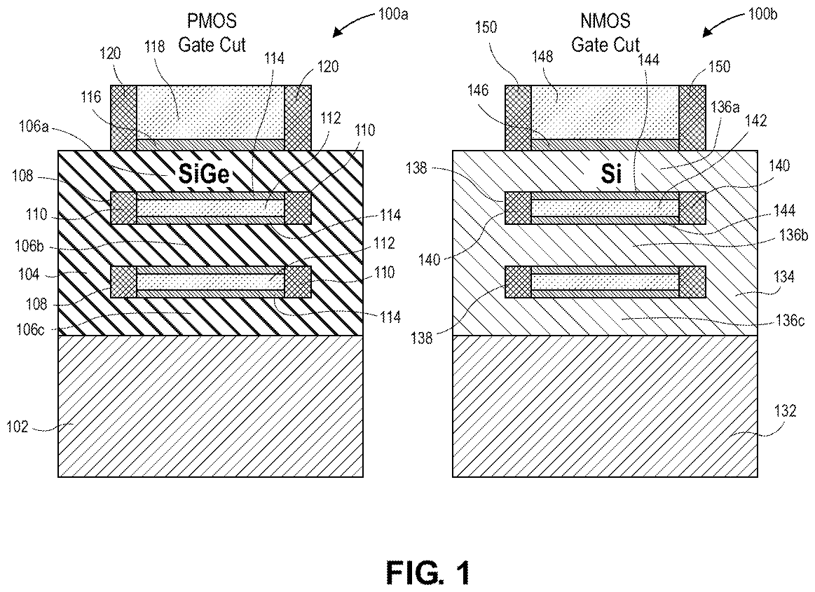

FIG. 1 shows a cross section side view of a PMOS and a NMOS gate cut that include dimpled spacers in a nano-ribbon structure, in accordance with various embodiments. PMOS gate cut 100a includes a substrate 102, a PMOS epitaxial 104 on the substrate 102, with nano-wires 106a-106c within the PMOS epitaxial 104. In embodiments, the PMOS epitaxial 104 may include silicon germanium (SiGe). The nano-wires 106a-106c may be separated by a gate structure 108 that includes a dimple spacer 110 that surrounds an edge of a gate metal 112. The gate metal 112 may have a high-k dielectric material 114 on a first side of the gate material 112 and on a second side of the gate material 112 opposite the first side. At the top of the PMOS epitaxial 104 there is a high-k dielectric material 116 and a gate material 118 on top of the high-k dielectric material 116. A spacer material 120 may surround the gate material 118 and the high-k dielectric material 116. Embodiments may include any number of nano-wires.

NMOS gate cut 100b, which may be similar to PMOS gate cut 100a, includes an NMOS epitaxial 134 on the substrate 132, with nano-wires 136a-136c within the NMOS epitaxial 134. In embodiments, the NMOS epitaxial 134 may include silicon (Si). The nano-wires 136a-136c may be separated by a gate structure 138 that includes a dimple spacer 140 that surrounds an edge of a gate metal 142. The gate metal 142 may have a high-k dielectric material 144 on a first side of the gate material 142 and on a second side of the gate material 142 opposite the first side. At the top of the NMOS epitaxial 134 there is a high-k dielectric material 146 and a gate material 148 on top of the high-k dielectric material 146. A spacer material 150 may surround the gate material 148 and the high-k dielectric material 146.

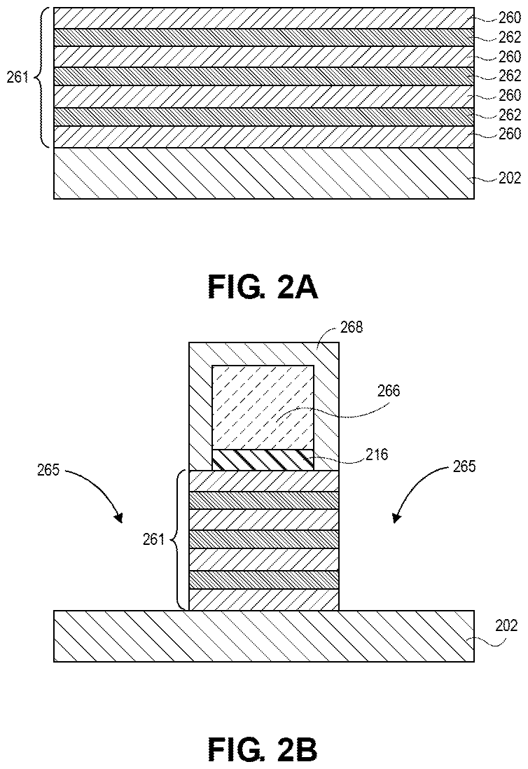

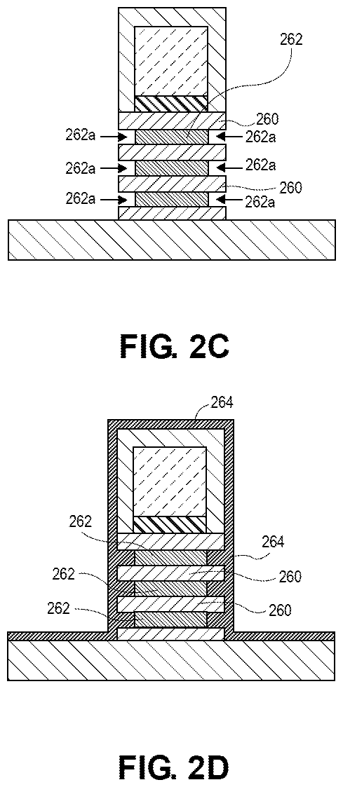

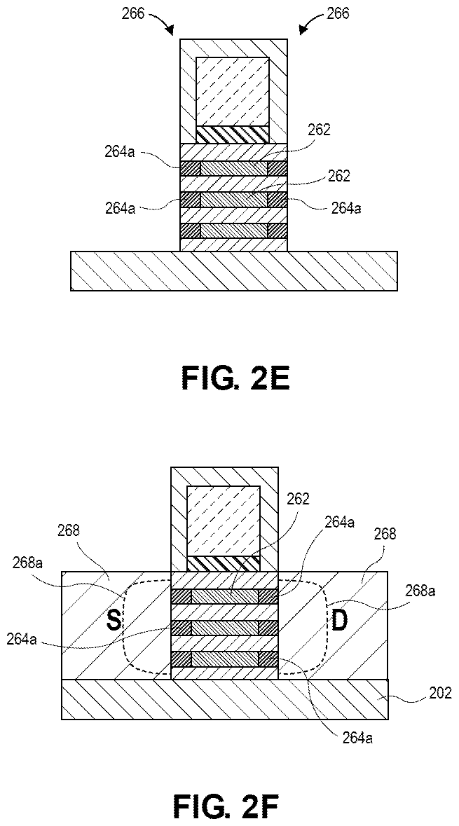

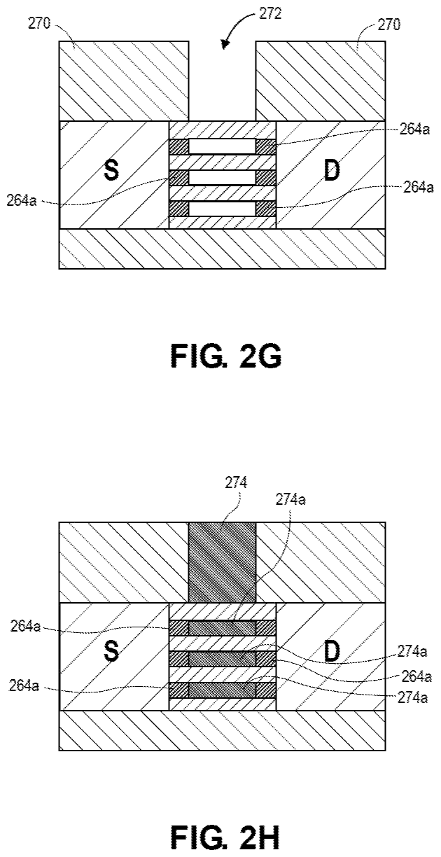

FIGS. 2A-2H show cross section side views of stages in a legacy manufacturing process for creating a nano-ribbon structure with dimpled spacers.

FIG. 2A shows a stage in a legacy manufacturing process where alternating layers of Si 260 and SiGe 262 are formed to create structure 261. Structure 261 may be formed on a substrate 202, which may be similar to substrate 102 of FIG. 1.

FIG. 2B shows a stage in the legacy manufacturing process where removed portions 265 of the structure 261 are removed by etching down to the substrate 202. A dummy gate 266, which will be removed at the replacement metal gate step, is placed on the structure 261. A dummy gate oxide 216, is placed below the dummy gate 266, and on top of the structure 261. A spacer 268 is added in order to form the dimple spacers.

FIG. 2C shows a stage in the legacy manufacturing process where an etch process is performed to etch part of the SiGe 262a underneath the Si 260 in order to make the space for a legacy dimple spacer.

FIG. 2D shows a stage in the legacy manufacturing process where an inner spacer material 264 is applied, and fills the etched part of the SiGe 262a.

FIG. 2E shows a stage in a legacy manufacturing process where the legacy dimple spacer is being formed by removing the inner spacer material 264 for all areas outside of the cavity that was formed in the etch for FIG. 2D. Note that the portions of the inner spacer 264a form the legacy dimple spacers.

FIG. 2F shows a stage in a legacy manufacturing process where epitaxial 268 SiGe sources and drains are epitaxially grown from the substrate 202. Note that the areas 268a may have defects or other distortions during the epitaxial 268 growth due to the presence of the inner spacers 264a. These defects form due to growth of multiple disconnected semiconductor regions which merge together forming defects. These defects reduce the stress from in the epitaxial 268 SiGe source and drains. It should be appreciated that the areas 268a may occur anywhere within the epitaxial 268.

FIG. 2G shows a stage in the legacy manufacturing process where an interlayer dielectric (ILD) layer 270 is added above the epitaxial 268 sources and drains, and the dummy gate 266 is removed. An etch process is used to create cavity 272 by removing the SiGe layers 262 shown in FIG. 2F.

FIG. 2H shows a stage in the legacy manufacturing process where a gate insulator and gate metal 274 is inserted into the cavity 272 to form gate structures 274a, which may be similar to gate structures 112 of FIG. 1.

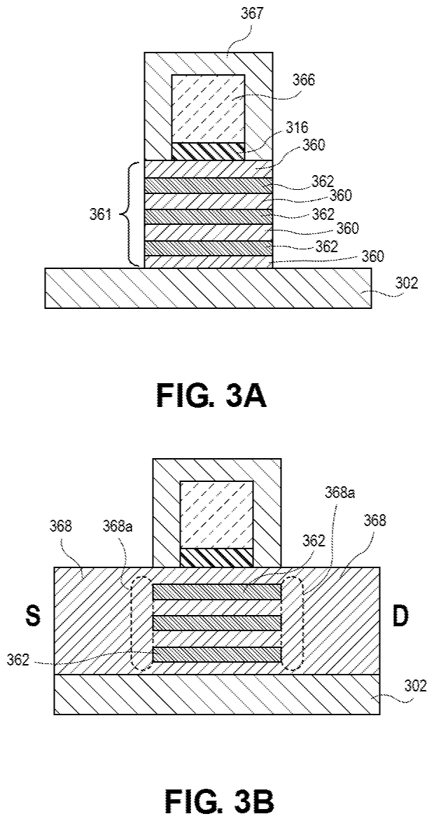

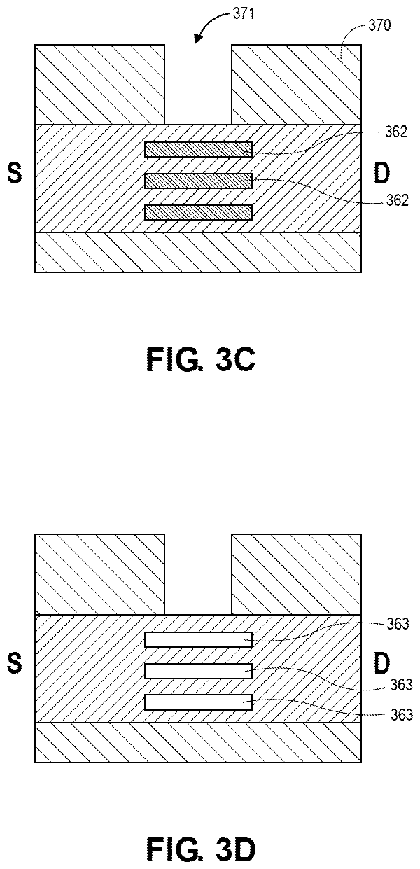

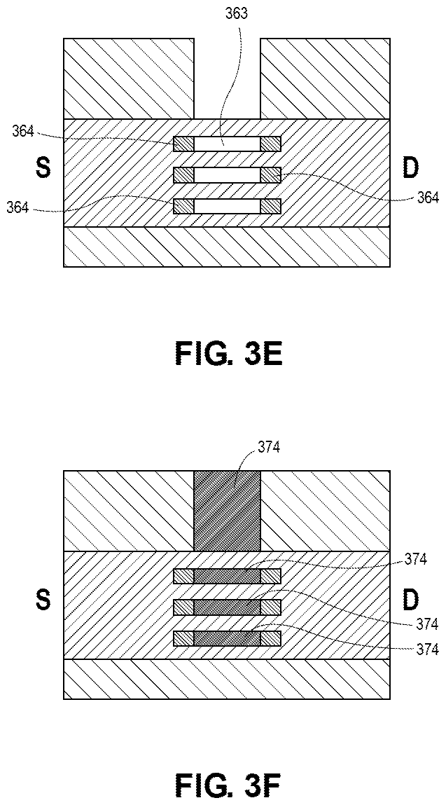

FIGS. 3A-3F show cross section side views of stages in a manufacturing process for creating nano-ribbon structures with dimpled spacers with defect free epitaxial layers, in accordance with various embodiments.

FIG. 3A, shows a cross section side view of a stage in an embodiment of a manufacturing process where alternating layers of Si 360 and SiGe 362 are formed to create structure 361. Structure 361 is formed on a substrate 302, which may be similar to substrate 102 of FIG. 1. A dummy gate oxide 316, which may be similar to dummy gate oxide 216 of FIG. 2B, may be formed on the structure 361. In embodiments, the dummy gate oxide 316 may include a high-k dielectric material. A dummy gate 366 is placed on the gate insulator 316, and is surrounded by spacer 367.

FIG. 3B shows a cross section side view of a stage in an embodiment of a manufacturing process where Si epitaxial 368 is grown from the substrate 302. Note that the growth of the Si epitaxial 368a proximate to the SiGe layers 362 grow uniformly with no defects that occur during growth. This results in larger stress in the SIGe epitaxial 368 source and drain regions and SiGe channels.

FIG. 3C shows a cross section side view of a stage in an embodiment of a manufacturing process where dummy gate 366 and spacer 367 are removed, and a layer 370, which may be similar to layer 270 of FIG. 2G, is placed and patterned, forming an opening 371.

FIG. 3D shows a cross section side view of a stage in an embodiment of a manufacturing process where an etch is applied through opening 371 to etch the SiGe 362 and expose cavities 363.

FIG. 3E shows a cross section side view of a stage in an embodiment of a manufacturing process where the dimpled spacer 364 is applied to edges of the cavities 363. In embodiments, the dimpled spacer 364 may be used to reduce capacitance of the transistor structure. In embodiments, the dimpled spacer 364 may be applied using atomic layer deposition (ALD) techniques combined with anisotropic etch back.

FIG. 3F shows a cross section side view of a stage in an embodiment of a manufacturing process where a gate metal 374, which may be similar to gate metal 274 of FIG. 2H, is inserted. In embodiments, there may be a gate insulator layer (not shown) at the top and/or bottom of the gate metal 374. The gate insulator layer (not shown) may be a high-k layer.

It should be noted that the processes described with respect to FIG. 3A-3F as described above are used to produce an NMOS device. To produce a PMOS device, in embodiments, the same stages may be used, except with Si replacing SiGe, and SiGe replacing Si.

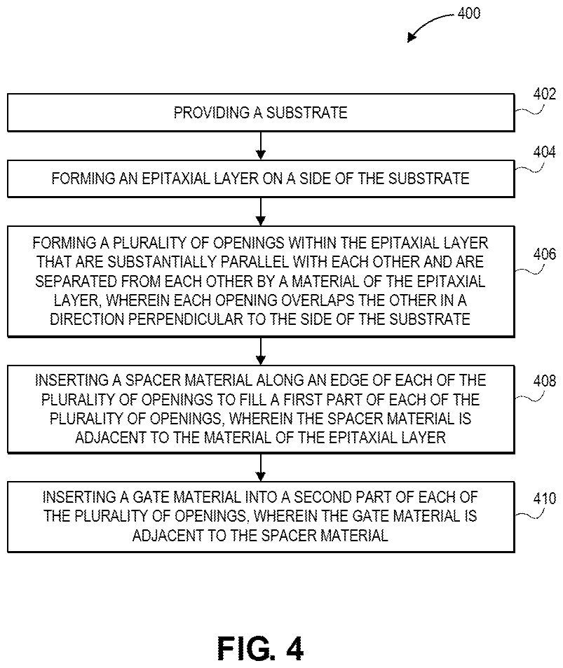

FIG. 4 illustrates an example process for manufacturing a package that includes a hermetic seal for a transistor structure that includes metal on both sides, in accordance with various embodiments. Process 400 may be implemented using the techniques and/or embodiments described herein, and in particular with respect to FIGS. 1-3F.

At block 402, the process may include providing a substrate. In embodiments, the substrate may be similar to substrate 102, 132 of FIG. 1, or substrate 302 of FIGS. 3A-3F.

At block 404, the process may further include forming an epitaxial layer on a side of the substrate. In embodiments, the epitaxial layer may be similar to epitaxial layer 368 of FIG. 3B.

At block 406, the process may further include forming a plurality of openings within the epitaxial layer that are substantially parallel with each other and are separated from each other by a material of the epitaxial layer, wherein each opening overlaps the other in a direction perpendicular to the side of the substrate. In embodiments, the plurality of openings may be similar to cavities 363 of FIG. 3D.

At block 408, the process may further include inserting a spacer material along an edge of each of the plurality of openings to fill a first part of each of the plurality of openings, wherein the spacer material is adjacent to the material of the epitaxial layer. In embodiments, the spacer material may be similar to dimpled spacer 364 of FIG. 3E.

At block 410, the process may further include inserting a gate material into a second part of each of the plurality of openings, wherein the gate material is adjacent to the spacer material. In embodiments, the gate material may be similar to gate metal 374 of FIG. 3F.

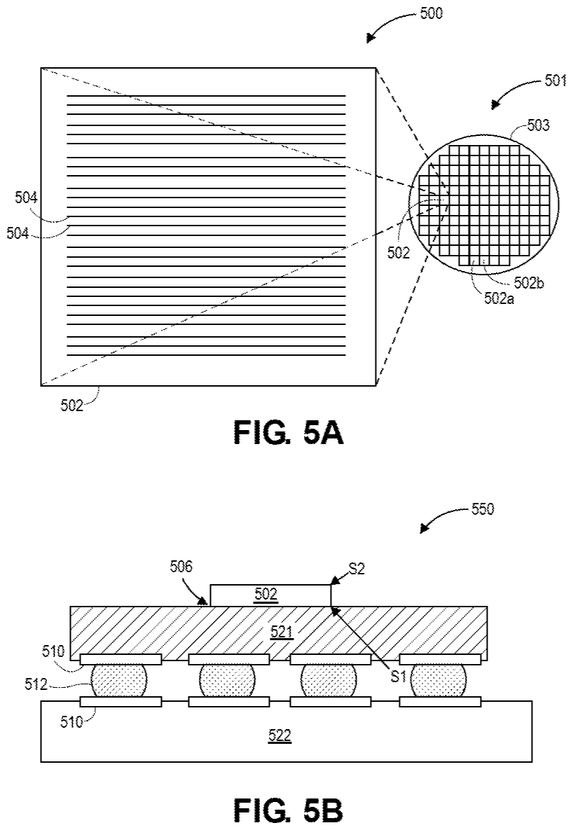

FIGS. 5A-5B schematically illustrate a top view of an example die in wafer form and in singulated form, and a cross section side view of a package assembly, in accordance with various embodiments. FIGS. 5A-5B schematically illustrate a top view of an example die in wafer form and in singulated form, and a cross section side view of a package assembly, in accordance with various embodiments. FIG. 5A schematically illustrates a top view of an example die 502 in a wafer form 501 and in a singulated form 500, in accordance with some embodiments. In some embodiments, die 502 may be one of a plurality of dies, e.g., dies 502, 502a, 502b, of a wafer 503 comprising semiconductor material, e.g., silicon or other suitable material. The plurality of dies, e.g., dies 502, 502a, 502b, may be formed on a surface of wafer 503. Each of the dies 502, 502a, 502b, may be a repeating unit of a semiconductor product that includes devices as described herein. For example, die 502 may include circuitry having elements such as capacitors and/or inductors 504 (e.g., fin structures, nano-wires, and the like) that provide a channel pathway for mobile charge carriers in transistor devices. Although one or more capacitors and/or inductors 504 are depicted in rows that traverse a substantial portion of die 502, it is to be understood that one or more capacitors and/or inductors 504 may be configured in any of a wide variety of other suitable arrangements on die 502 in other embodiments.

After a fabrication process of the device embodied in the dies is complete, wafer 503 may undergo a singulation process in which each of dies, e.g., die 502, is separated from one another to provide discrete “chips” of the semiconductor product. Wafer 503 may be any of a variety of sizes. In some embodiments, wafer 503 has a diameter ranging from about 25.4 mm to about 450 mm. Wafer 503 may include other sizes and/or other shapes in other embodiments. According to various embodiments, the one or more capacitors and/or inductors 504 may be disposed on a semiconductor substrate in wafer form 501 or singulated form 500. One or more capacitors and/or inductors 504 described herein may be incorporated in die 502 for logic, memory, or combinations thereof. In some embodiments, one or more capacitors and/or inductors 504 may be part of a system-on-chip (SoC) assembly.

FIG. 5B schematically illustrates a cross-section side view of an integrated circuit (IC) assembly 550, in accordance with some embodiments. In some embodiments, IC assembly 550 may include one or more dies, e.g., die 502, electrically or physically coupled with a package substrate 521. Die 502 may include one or more capacitors and/or inductors 504 as described herein. In some embodiments, package substrate 521 may be electrically coupled with a circuit board 522 as is well known to a person of ordinary skill in the art. Die 502 may represent a discrete product made from a semiconductor material (e.g., silicon) using semiconductor fabrication techniques such as thin film deposition, lithography, etching, and the like. In some embodiments, die 502 may be, include, or be a part of a processor, memory, SoC or ASIC in some embodiments.

Die 502 can be attached to package substrate 521 according to a wide variety of suitable configurations including, for example, being directly coupled with package substrate 521 in a flip-chip configuration, as depicted. In the flip-chip configuration, an active side S1 of die 502 including circuitry is attached to a surface of package substrate 521 using hybrid bonding structures as described herein that may also electrically couple die 502 with package substrate 521. Active side S1 of die 502 may include multi-threshold voltage transistor devices as described herein. An inactive side S2 of die 502 may be disposed opposite to active side S1.

In some embodiments, package substrate 521 is an epoxy-based laminate substrate having a core and/or build-up layers such as, for example, an Ajinomoto Build-up Film (ABF) substrate. Package substrate 521 may include other suitable types of substrates in other embodiments including, for example, substrates formed from glass, ceramic, or semiconductor materials.

Package substrate 521 may include electrical routing features configured to route electrical signals to or from die 502. The electrical routing features may include pads or traces (not shown) disposed on one or more surfaces of package substrate 521 and/or internal routing features (not shown) such as trenches, vias, or other interconnect structures to route electrical signals through package substrate 521. In some embodiments, package substrate 521 may include electrical routing features such as pads (not shown) configured to receive the respective die-level interconnect structures 506 of die 502.

Circuit board 522 may be a printed circuit board (PCB) comprising an electrically insulative material such as an epoxy laminate. Circuit board 522 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 502 through circuit board 522. Circuit board 522 may comprise other suitable materials in other embodiments. In some embodiments, circuit board 522 is a motherboard as is well known to a person of ordinary skill in the art.

Package-level interconnects such as, for example, solder balls 512 may be coupled to one or more pads 510 on package substrate 521 and/or on circuit board 522 to form corresponding solder joints that are configured to further route the electrical signals between package substrate 521 and circuit board 522. Pads 510 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 521 with circuit board 522 may be used in other embodiments.

IC assembly 550 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 502 and other components of IC assembly 550 may be used in some embodiments.

A person of ordinary skill in the art should recognize that any known semiconductor device fabricated using any known semiconductor process that may benefit from the principles described herein.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention. A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nano-ribbon and nano-wire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

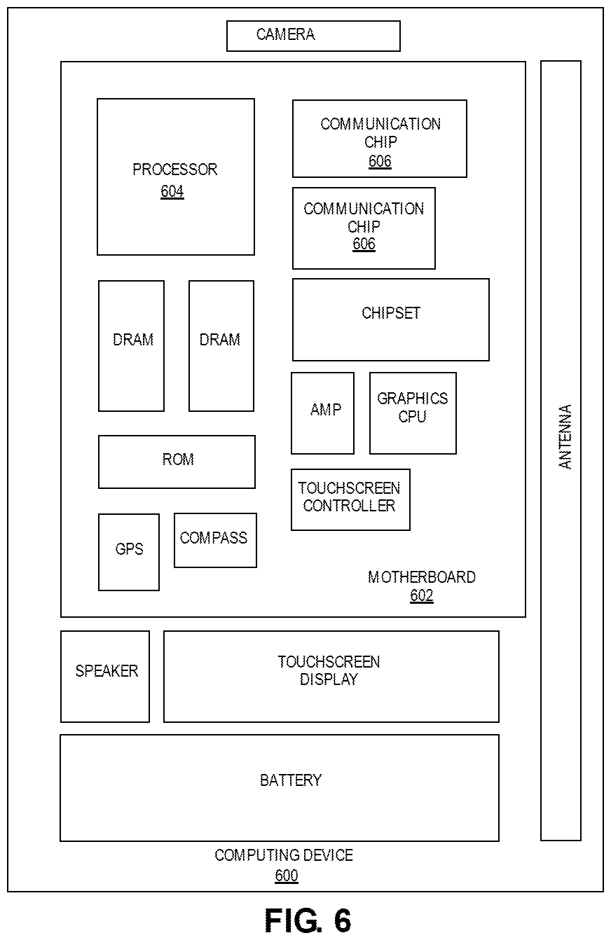

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as MOS-FET transistors built in accordance with implementations of the invention.

In further implementations, another component housed within the computing device 600 may contain an integrated circuit die that includes one or more devices, such as MOS-FET transistors built in accordance with implementations of the invention.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

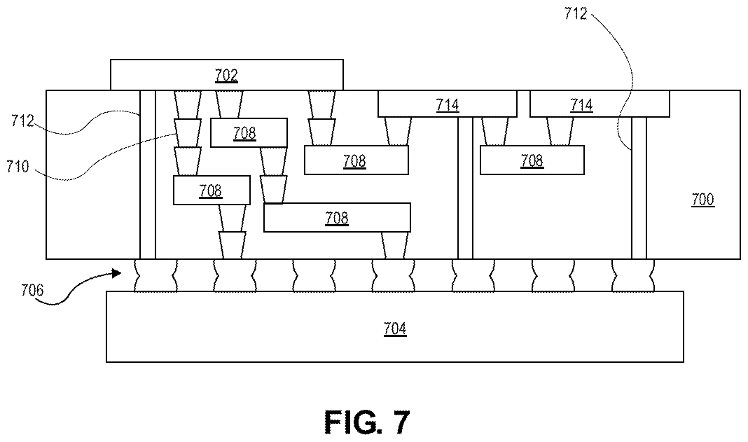

FIG. 7 illustrates an interposer 700 that includes one or more embodiments of the invention. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer 700 may be formed of alternate rigid or flexible materials that may include the same materials described above for use in a semiconductor substrate, such as silicon, germanium, and other group III-V and group IV materials.

The interposer 700 may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with embodiments of the invention, apparatuses or processes disclosed herein may be used in the fabrication of interposer 700.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a transistor structure comprising: an epitaxial material; a plurality of layers of gate material that extend through the epitaxial material, wherein each of the plurality of layers are in a separate plane, wherein the plurality of layers are substantially parallel to each other, and wherein the epitaxial material separates each of the plurality of layers from the other; wherein a layer of the plurality of layers of gate material includes a spacer that surrounds an edge of the layer between a first side of the layer and a second side of the layer opposite the first side; and wherein a volume of the epitaxial material adjacent to the spacer for at least some of the plurality of layers of gate material is stress and defect free.

Example 2 include the transistor structure of example 1, or of any other example or embodiment described herein, wherein the epitaxial material includes a selected one of: silicon (Si) or silicon germanium (SiGe).

Example 3 includes the transistor structure of example 1, or of any other example or embodiment described herein, wherein a material of the spacer includes a selected one or more of: silicon, nitrogen, oxygen, silicon nitride, silicon oxide, silicon oxynitride, silicon nitride oxide, or carbon films.

Example 4 includes the transistor structure of example 1, or of any other example or embodiment described herein, wherein each of the plurality of layers of gate material includes a high-k dielectric material on a top surface of the layer and the high-k dielectric material on a bottom surface of the layer opposite the top surface of the layer.

Example 5 includes the transistor structure of example 4, or of any other example or embodiment described herein, wherein each of the plurality of layers of gate material includes the high-k dielectric material that surrounds edges of the layer between the top surface of the layer and the bottom surface of the layer.

Example 6 includes the transistor structure of example 1, or of any other example or embodiment described herein, wherein the gate material includes a selected one or more of: tungsten, titanium, titanium nitride, silver, indium, or cadmium.

Example 7 includes the transistor structure of example 1, or of any other example or embodiment described herein, wherein the transistor structure is on a substrate, the substrate includes a selected one of: Si or buried oxide (BOX).

Example 8 includes the transistor structure of example 1, or of any other example or embodiment described herein, wherein the plurality of layers overlap each other in a direction perpendicular to the plurality of planes.

Example 9 includes the transistor structure of example 1, or of any other example or embodiment described herein, wherein the transistor structure includes a plurality of transistor structures.

Example 10 is a package comprising: a first epitaxial material and a second epitaxial material; a first plurality of layers of gate material that extend through the first epitaxial material, wherein each of the first plurality of layers are substantially parallel to each other, and wherein the first epitaxial material separates each of the first plurality of layers from another; wherein a layer of the first plurality of layers of gate material includes a spacer that surrounds an edge of the layer between a first side of the layer and a second side of the layer opposite the first side; and a second plurality of layers of gate material that extend through the second epitaxial material, wherein each of the second plurality of layers are substantially parallel to each other, and wherein the second epitaxial material separates each of the second plurality of layers from another; wherein a layer of the second plurality of layers of gate material includes a spacer that surrounds an edge of the layer between a first side of the layer and a second side of the layer opposite the first side; and wherein a volume of the first epitaxial material adjacent to the spacer of each of the first plurality of layers of gate material is defect free, and wherein a volume of the second epitaxial material adjacent to the spacer of each of the second plurality of layers of gate material is defect free.

Example 11 includes the package of example 10, or of any other example or embodiment described herein, wherein the first epitaxial material and the second epitaxial material are a same material.

Example 12 includes the package of example 10, or of any other example or embodiment described herein, wherein the first epitaxial material is silicon (Si), and the second epitaxial material is silicon germanium (SiGe).

Example 13 includes the package of example 10, or of any other example or embodiment described herein, wherein the first epitaxial material and the second epitaxial material are on a same substrate.

Example 14 includes the package of example 13, or of any other example or embodiment described herein, wherein the substrate is a silicon substrate.

Example 15 includes the package of example 10, or of any other example or embodiment described herein, wherein a material for the spacer includes a selected one or more of: silicon, nitrogen, oxygen, silicon nitride, silicon oxide, silicon oxynitride, silicon nitride oxide, or carbon films.

Example 16 includes the package of example 10, or of any other example or embodiment described herein, wherein the gate material includes a selected one or more of: tungsten, titanium, titanium nitride, silver, indium, or cadmium.

Example 17 is a method comprising: providing a substrate; forming an epitaxial layer on a side of the substrate; forming a plurality of openings within the epitaxial layer that are substantially parallel with each other and are separated from each other by a material of the epitaxial layer, wherein each opening overlaps the other in a direction perpendicular to the side of the substrate; inserting a spacer material along an edge of each of the plurality of openings to fill a first part of each of the plurality of openings, wherein the spacer material is adjacent to the material of the epitaxial layer; and inserting a gate material into a second part of each of the plurality of openings, wherein the gate material is adjacent to the spacer material.

Example 18 includes the method of example 17, or of any other example or embodiment described herein, wherein forming an epitaxial layer further includes: forming alternating layers of the material of the epitaxial layer and another material on the side of the substrate; forming a dummy gate on top of the formed alternating layers of the epitaxial material and the other material; etching a portion of the formed alternating layers down to the side of the substrate that are not underneath the dummy gate; and growing additional epitaxial material from the side of the substrate; and wherein forming a plurality of openings further includes: removing the formed dummy gate; and etching the other material.

Example 19 includes the method of example 18, or of any other example or embodiment described herein, wherein the material of the epitaxial layer is silicon (Si) and the other material is silicon germanium (SiGe), or wherein the material of the epitaxial layer is SiGe and the other material is Si.

Example 20 includes the method of example 17, or of any other example or embodiment described herein, wherein inserting the spacer material further includes depositing the spacer material using atomic layer deposition (ALD).

What is claimed is:

1. A transistor structure comprising:
an epitaxial material;
a plurality of layers of gate material that extend through the epitaxial material,
wherein each of the plurality of layers are in a separate plane,
wherein the plurality of layers are substantially parallel to each other, and
wherein the epitaxial material separates each of the plurality of layers from the other; and
wherein a layer of the plurality of layers of gate material includes a spacer that surrounds an edge of the layer between a first side of the layer and a second side of the layer opposite the first side.

2. The transistor structure of claim 1, wherein a volume of the epitaxial material adjacent to the spacer for at least some of the plurality of layers of gate material is stress and defect free.

3. The transistor structure of claim 1, wherein the epitaxial material includes a selected one of: silicon (Si) or silicon germanium (SiGe).

4. The transistor structure of claim 1, wherein a material of the spacer includes a selected one or more of: silicon, nitrogen, oxygen, silicon nitride, silicon oxide, silicon oxynitride, silicon nitride oxide, or carbon films.

5. The transistor structure of claim 1, wherein each of the plurality of layers of gate material includes a high-k dielectric material on a top surface of the layer and the high-k dielectric material on a bottom surface of the layer opposite the top surface of the layer.

6. The transistor structure of claim 5, wherein each of the plurality of layers of gate material includes the high-k dielectric material that surrounds edges of the layer between the top surface of the layer and the bottom surface of the layer.

7. The transistor structure of claim 1, wherein the gate material includes a selected one or more of: tungsten, titanium, titanium nitride, silver, indium, or cadmium.

8. The transistor structure of claim 1, wherein the transistor structure is on a substrate, the substrate includes a selected one of: Si or buried oxide (BOX).

9. The transistor structure of claim 1, wherein the plurality of layers overlap each other in a direction perpendicular to the plurality of planes.

10. The transistor structure of claim 1, wherein the transistor structure includes a plurality of transistor structures.

11. A package comprising:
a first epitaxial material and a second epitaxial material;
a first plurality of layers of gate material that extend through the first epitaxial material, wherein each of the first plurality of layers are substantially parallel to each other, and wherein the first epitaxial material separates each of the first plurality of layers from another;
wherein a layer of the first plurality of layers of gate material includes a spacer that surrounds an edge of the layer between a first side of the layer and a second side of the layer opposite the first side; and
a second plurality of layers of gate material that extend through the second epitaxial material, wherein each of the second plurality of layers are substantially parallel to each other, and wherein the second epitaxial material separates each of the second plurality of layers from another;
wherein a layer of the second plurality of layers of gate material includes a spacer that surrounds an edge of the layer between a first side of the layer and a second side of the layer opposite the first side; and
wherein a volume of the first epitaxial material adjacent to the spacer of each of the first plurality of layers of gate material is defect free, and wherein a volume of the second epitaxial material adjacent to the spacer of each of the second plurality of layers of gate material is defect free.

12. The package of claim 11, wherein the first epitaxial material and the second epitaxial material are a same material.

13. The package of claim 11, wherein the first epitaxial material is silicon (Si), and the second epitaxial material is silicon germanium (SiGe).

14. The package of claim 11, wherein the first epitaxial material and the second epitaxial material are on a same substrate.

15. The package of claim 14, wherein the substrate is a silicon substrate.

16. The package of claim 11, wherein a material for the spacer includes a selected one or more of: silicon, nitrogen, oxygen, silicon nitride, silicon oxide, silicon oxynitride, silicon nitride oxide, or carbon films.

17. The package of claim 11, wherein the gate material includes a selected one or more of: tungsten, titanium, titanium nitride, silver, indium, or cadmium.

18. A method comprising:
providing a substrate;
forming an epitaxial layer on a side of the substrate;
forming a plurality of openings within the epitaxial layer that are substantially parallel with each other and are separated from each other by a material of the epitaxial layer, wherein each opening overlaps the other in a direction perpendicular to the side of the substrate;
inserting a spacer material along an edge of each of the plurality of openings to fill a first part of each of the plurality of openings, wherein the spacer material is adjacent to the material of the epitaxial layer; and
inserting a gate material into a second part of each of the plurality of openings, wherein the gate material is adjacent to the spacer material.

19. The method of claim 18, wherein forming an epitaxial layer further includes:
forming alternating layers of the material of the epitaxial layer and another material on the side of the substrate;
forming a dummy gate on top of the formed alternating layers of the epitaxial material and the other material;
etching a portion of the formed alternating layers down to the side of the substrate that are not underneath the dummy gate; and
growing additional epitaxial material from the side of the substrate; and
wherein forming a plurality of openings further includes:
removing the formed dummy gate; and
etching the another material.

20. The method of claim 19, wherein the material of the epitaxial layer is silicon (Si) and the other material is silicon germanium (SiGe), or wherein the material of the epitaxial layer is SiGe and the other material is Si.

21. The method of claim 18, wherein inserting the spacer material further includes depositing the spacer material using atomic layer deposition (ALD).
